(19) United States
(12) Patent Application Publication
(10) Pub. No.: US 2015/0354797 A1
(43) Pub. Date: Dec. 10, 2015

(54) Flexible Circuit Board and Illumination Device Comprising the Flexible Circuit Board

(71) Applicant: OSRAM GMBH, München (DE)

(72) Inventors: Yabin Luo, Shenzhen (CN); Pengfei An, Shenzhen (CN); Yuan Lu, Shenzhen (CN); Yuanyuan He, Shenzhen (CN)

(21) Appl. No.: 14/759,934

(22) PCT Filed: Dec. 19, 2013
(86) PCT No.: PCT/EP2013/077503

§ 371 Date: Jul. 9, 2015

(30) Foreign Application Priority Data
Jan. 22, 2013 (CN) 201310023748.9

(51) Int. Cl. F21V 23/00; H05K 1/18; H05K 1/02; F21V 3/04; F21S 4/00

(52) U.S. Cl. CPC F21V 23/005; F21V 3/0409; F21S 4/005; H05K 1/028; H05K 1/189; F21Y 2103/003

(57) ABSTRACT

Various embodiments may relate to a flexible circuit board for an illumination device. The flexible circuit board may include a plurality of device mounting sections, and connection sections connected between adjacent device mounting sections. The plurality of device mounting sections are spaced apart from one another in the longitudinal direction of the entire flexible circuit board.

### RELATED APPLICATIONS

The present application is a national stage entry according to 35 U.S.C. §371 of PCT application No.: PCT/EP2013/077503 filed on Dec. 19, 2013, which claims priority from Chinese application No.: 201310023748.9 filed on Jan. 22, 2013, and is incorporated herein by reference in its entirety.

### TECHNICAL FIELD

Various embodiments may relate to a flexible circuit board for an illumination device. In addition, various embodiments further relate to an illumination device including the flexible circuit board, especially a flexible light strip.

### BACKGROUND

In outdoor illumination, especially in advertising illumination for the purpose of propaganda, flexible light strips are usually needed to sketch out an object to be illuminated. An object to be illuminated usually has an irregular outline, which requires that the light strips can be bent in various directions. Traditional light strips are usually unable to meet the requirement.

As LED illumination technology has the advantages of long lifespan, high luminous efficiency, environmental protection and low cost, people more and more frequently use LED chips as light sources to replace traditional illumination devices. In the current market, there also appear flexible light strips with LED chips as light sources. Such flexible light strip comprises a flexible circuit board and a plurality of LED chips arranged on the flexible circuit board, and usually, an elastic transparent potting material is further needed to encapsulate the flexible circuit board and the LED chips provided thereon, in order to meet the sealing requirement. However, such flexible circuit board usually can be bent only in a direction perpendicular to the mounting surface of the circuit board, but can hardly be bent, or even cannot be bent, in a direction parallel to the mounting surface, and the circuit board is likely to be damaged if bent in this direction, which greatly limits the scope of application and the conditions of use of the flexible light strip.

### SUMMARY

Various embodiments relate to a flexible circuit board for an illumination device, which can be freely bent in various directions, without damaging the circuit board itself. In addition, the circuit board is low in cost, and is easy to manufacture. Further, various embodiments also relate to an illumination device including the flexible circuit board, especially a flexible light strip.

Various embodiments provide a flexible circuit board for an illumination device, viz. the flexible circuit board includes a plurality of device mounting sections, and connection sections connected between adjacent device mounting sections, wherein the a plurality of device mounting sections are spaced apart from one another in the longitudinal direction of the entire flexible circuit board. According to various embodiments, the connection sections are arranged with respect to the device mounting sections such that the flexible circuit board may be flexibly bent at least in a direction parallel to a mounting surface of the device mounting sections. For this reason, the flexible circuit board according to various embodiments is improved based on the traditional flexible circuit board, which not only may be flexibly bent in a direction perpendicular to the mounting surface of the device mounting sections, but also maybe flexibly bent in other directions than this direction. This greatly improves the bending performance of the flexible circuit board according to various embodiments in various directions, allowing the flexible circuit board to have higher application flexibility. According to various embodiments, the wording “flexible bending” should be understood as that the flexible circuit board could be bent in a relative wide extent without damaging the flexible circuit board. At same time, the bending abilities of the flexible circuit board according to various embodiments in all direction are almost same.

According to various embodiments, the connection section forms a predetermined angle with respect to the mounting surface of the device mounting sections. That is, the connection sections are not in the same plane as the mounting surface. The connection sections and the device mounting sections are usually flat plates having relatively small thickness, and flat plates may be easily bent in the thickness direction, but may hardly be bent in the width direction. If the connection sections and the mounting surface, that is, the device mounting sections, are arranged to form a predetermined angle, when the flexible circuit board is bent in the width direction, the device mounting sections spaced apart from one another will get close to each other at one side of the device mounting sections, and at this time, the connection sections are at least not bent in the width direction thereof, but at least bent in the thickness direction, which obviously improves the bending capability of the flexible circuit board in the width direction, that is, in the direction parallel to the mounting surface.

According to various embodiments, one of two adjacent connection sections is arranged at a first side of an adjacent device mounting section, and the other of the two adjacent connection sections is arranged at a second side of the device mounting section facing the first side. Viewed as a whole, the connection sections are arranged in a staggered manner on the two sides of the flexible circuit board in the longitudinal direction of the entire flexible circuit board, which significantly improves the bending performance of the flexible circuit board.

In various embodiments, adjacent device mounting sections and a connection section therebetween forms a sub-unit, wherein each of the sub-unit(s) forms a U-shaped structure, wherein the device mounting sections of each sub-unit form a part of an adjacent sub-unit. In the flexible circuit board, the U-shaped sub-units are interconnected, wherein two sides of one U shape respectively constitute one side of adjacent U shapes, and thereby, viewed as a whole, the flexible circuit board is formed into a zigzag structure.

In various embodiments, a gap between the adjacent device mounting sections forms a first deformation space, and a gap between adjacent connection sections on the same side as the device mounting sections forms a second deformation space. The two deformation spaces respectively allow the flexible circuit board to be bent in the direction perpendicular to the mounting surface and in the direction parallel to the mounting surface, without causing the adjacent connection sections and device mounting sections of the circuit board to press against each other.

In various embodiments, the predetermined angle between the connection section and the mounting surface of the device mounting sections is between 60° and 120, preferably 90°. The 90° angle can optimally achieve bending of the flexible circuit board in the direction parallel to the mounting surface.

In various embodiments, the device mounting sections and the connection sections are made in one piece, which reduces the manufacturing difficulty of the flexible circuit board. In practical applications, the flexible circuit board may be made of the same material as the conventional flexible circuit board. At the beginning of manufacturing, the flexible circuit board may be cut according to needs, and then is bent at a suitable position on the flexible circuit board, such that the connection section and the mounting surface of the device mounting sections form a predetermined angle.

Various embodiments further provide an illumination device including a light-emitting assembly, wherein the illumination device includes a flexible circuit board as described above, at least one light-emitting assembly being arranged on device mounting sections of the flexible circuit board.

According to various embodiments, the illumination device further includes a transparent potting material, and the flexible circuit board and the light-emitting assembly are encapsulated by the potting material. In various embodiments, the potting material is an elastic transparent silicone resin or PU.

Further according to various embodiments, the light-emitting assembly is an LED chip. LED chips have the advantages of long lifespan, high luminous efficiency and environmental protection.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the disclosed embodiments. In the following description, various embodiments described with reference to the following drawings, in which:

FIG. 1 is a schematic diagram of a flexible circuit board according to various embodiments;

FIG. 2 is a schematic diagram of a flexible circuit board mounted with a light-emitting assembly;

FIG. 3 is a top view of the flexible circuit board shown in FIG. 2;

FIG. 4 is a sectional view of an illumination device according to various embodiments in a longitudinal direction; and

FIG. 5 is a sectional view of an illumination device according to various embodiments in a transverse direction.

### DETAILED DESCRIPTION

In the following detailed description, reference is made to the accompanying drawings, which form a part hereof, and in which is shown by way of illustration specific embodiments in which the invention maybe practiced. Because components of embodiments can be positioned in a number of different orientations, the directional terminology is used for purposes of illustration and is in no way limiting. It is to be understood that other embodiments maybe utilized and structural or logical changes may be made without departing from the scope of the present invention. The following detailed description, therefore, is not to be taken in a limiting sense, and the scope of the present invention is defined by the appended claims.

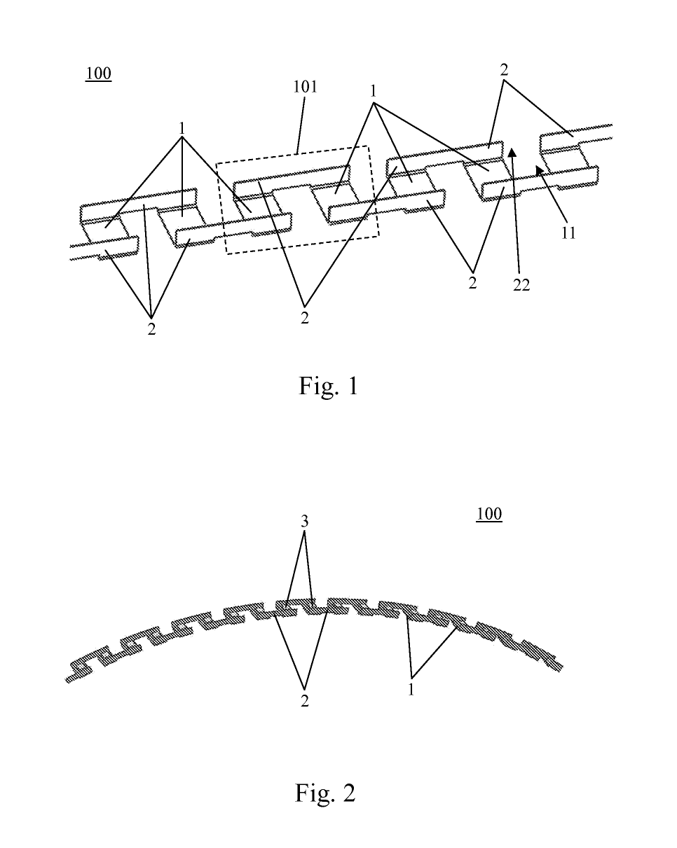

FIG. 1 is a schematic diagram of a flexible circuit board 100 according to various embodiments. As can be seen from the figure, the flexible circuit board 100 includes a plurality of device mounting sections 1 spaced apart from one another in the longitudinal direction of the entire flexible circuit board, and connection sections 2 connected between adjacent device mounting sections 1, the connection section 2 forms a predetermined angle with a mounting surface of the device mounting sections 1. In an embodiment of the present disclosure, the device mounting sections 1 and the connection sections 2 are flat plates having relatively small thickness, and flat plates can be easily bent in the thickness direction, that is, in the direction perpendicular to the mounting surface of the device mounting sections 1, but can hardly be bent in the width direction, that is, in the direction parallel to the mounting surface. If the connection sections 2 and the mounting surface, that is, the device mounting sections 1, are arranged to form a predetermined angle, when the flexible circuit board 100 is bent in the width direction, the device mounting sections 1 spaced apart from one another will get close to each other at one side of the device mounting sections, and at this time, the connection sections 2 are at least not bent in the width direction thereof, but at least bent in the thickness direction, which obviously improves the bending capability of the flexible circuit board 100 in the width direction. This special connection structure enables the flexible circuit board 100 to be bent at least in the direction parallel to the mounting surface of the device mounting sections 1. The predetermined angle between the connection section 2 and the mounting surface of the device mounting sections 1 is between 60° and 120°. In this embodiment, the predetermined angle is 90°. Of course, in other embodiments, the angle can be appropriately adjusted, for example, adjusted to 45°, 60° etc. Nevertheless, when the angle is 90°, the flexible circuit board 100 has the strongest bending capability.

In addition, as can be seen from FIG. 1, one of two adjacent connection sections 2 is connected with a first side of an adjacent device mounting section 1, and the other of the two adjacent connection sections 2 is on a second side of the device mounting section 1 facing the first side, such that adjacent device mounting sections 1 and a connection section 2 therebetween are connected into at least one sub-unit 101, wherein each of the sub-unit(s) 101 forms a U-shaped structure, wherein the device mounting sections 1 of each sub-unit 101 form a part of an adjacent sub-unit 101. In the flexible circuit board 100, the U-shaped sub-units 101 are interconnected, wherein two sides of one U shape respectively constitute one side of adjacent U shapes, and thereby, viewed as a whole, the flexible circuit board 100 is formed into a zigzag structure.

As the adjacent device mounting sections are spaced apart from each other, a gap therebetween forms a first deformation space 11, and a gap between adjacent connection sections 2 on the same side as the device mounting sections 1 forms a second deformation space 22. The two deformation spaces 11, 22 respectively allow the flexible circuit board 100 to be bent in the direction perpendicular to the mounting surface and in the direction parallel to the mounting surface, without causing the adjacent connection sections 2 and device mounting sections 1 of the circuit board to press against each other.

In this embodiment, the device mounting sections 1 and the connection sections 2 are made in one piece, which reduces the manufacturing difficulty of the flexible circuit board 100. In practical applications, the flexible circuit board 100 can be made of the same material as the conventional flexible circuit board. At the beginning of manufacturing, the flexible circuit board 100 can be cut according to needs, and then is bent at a suitable position on the flexible circuit board 100, such that the connection section 2 and the mounting surface of the device mounting sections 1 form a predetermined angle.

FIG. 2 is another schematic diagram of the flexible circuit board 100 according to various embodiments. As can be seen from FIG. 2, a light-emitting assembly 3 configured as an LED chip has already been mounted on the flexible circuit board 100. In this embodiment, each device mounting section 1 of the flexible circuit board 100 is provided with an LED chip. However, in other embodiments, a plurality of LED chips can be arranged on each device mounting section 1. In addition, as can be further seen from the figure, the flexible circuit board 100 has been bent in both the direction parallel to the mounting surface of the device mounting sections 1 and the direction perpendicular to the mounting surface of the device mounting sections 1, and the circuit board itself and the light-emitting assembly 3 mounted thereon are not damaged.

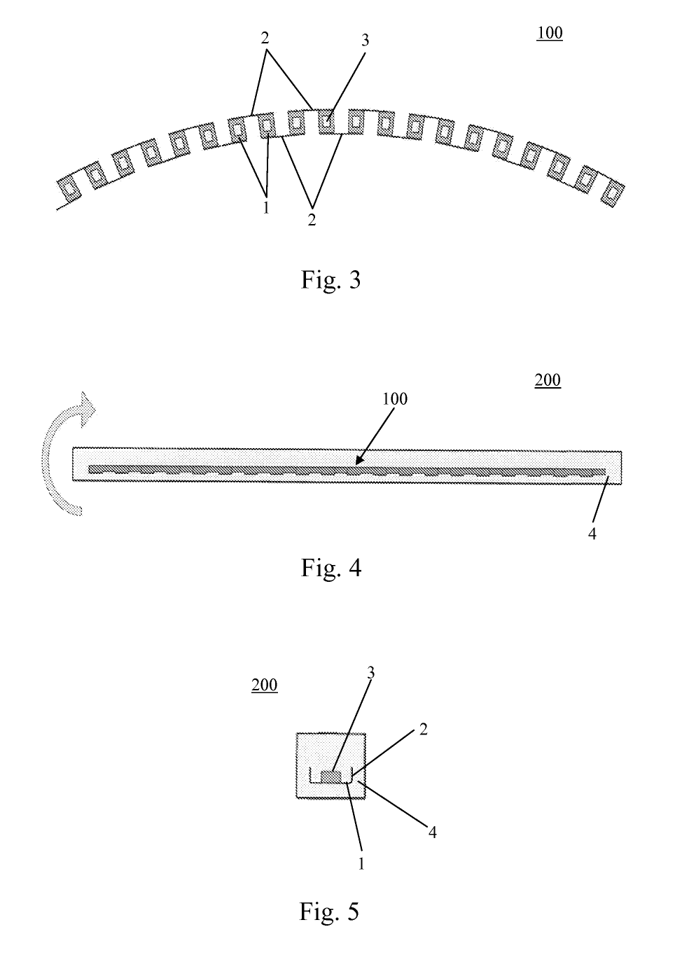

FIG. 3 is a top view of the flexible circuit board 100 shown in FIG. 2. As can be further seen from the figure clearly, the flexible circuit board 100 has been bent in the direction parallel to the mounting surface of the device mounting sections 1.

FIG. 4 is a sectional view of an illumination device 200 according to various embodiments in a longitudinal direction. As can be seen from the figure, the illumination device 200 includes a light-emitting assembly 3 and a flexible circuit board 100, at least one light-emitting assembly 3 is arranged on device mounting sections 1 of the flexible circuit board 100 (see FIG. 5). In addition, the illumination device 200 further includes a transparent potting material 4, and the flexible circuit board 100 and the light-emitting assembly 3 are encapsulated by the potting material 4. In this embodiment, the potting material 4 is an elastic transparent silicone resin or PU.

FIG. 5 is a sectional view of the illumination device 200 according to various embodiments in a transverse direction. As can be seen from the figure, the connection sections 2 are arranged to be perpendicular to the device mounting sections 1.

While the disclosed embodiments have been particularly shown and described with reference to specific embodiments, it should be understood by those skilled in the art that various changes in form and detail may be made therein without departing from the spirit and scope of the disclosed embodiments as defined by the appended claims. The scope of the disclosed embodiments is thus indicated by the appended claims and all changes which come within the meaning and range of equivalency of the claims are therefore intended to be embraced.

1. A flexible circuit board for an illumination device, the flexible circuit board comprising: a plurality of device mounting sections, and connection sections connected between adjacent device mounting sections, wherein the plurality of device mounting sections are spaced apart from one another in the longitudinal direction of the entire flexible circuit board.

2. The flexible circuit board according to claim 1, wherein the connection section forms a predetermined angle with respect to a mounting surface of the device mounting sections.

3. The flexible circuit board according to claim 1, wherein one of two adjacent connection sections is arranged at a first side of an adjacent device mounting section, and the other of the two adjacent connection sections is arranged at a second side of the device mounting section opposite to the first side.

4. The flexible circuit board according to claim 1, wherein adjacent device mounting sections and a connection section therebetween forms a sub-unit, wherein the device mounting sections of each sub-unit form a part of an adjacent sub-unit.

5. The flexible circuit board according to claim 4, wherein each sub-unit forms a U-shaped structure.

6. The flexible circuit board according to claim 3, wherein a gap between the adjacent device mounting sections forms a first deformation space, and a gap between the adjacent connection sections forms a second deformation space.

7. The flexible circuit board according to claim 2, wherein the predetermined angle is between 60° and 120°.

8. The flexible circuit board according to claim 7, wherein the predetermined angle is 90°.

9. The flexible circuit board according to claim 1, wherein the device mounting sections and the connection sections are made in one piece.

10. An illumination device, comprising a light source, and a flexible circuit board,
the flexible circuit board: a plurality of device mounting sections, and connection sections connected between adjacent device mounting sections, wherein the plurality of device mounting sections are spaced apart from one another in the longitudinal direction of the entire flexible circuit board,
wherein at least one light source is arranged on the device mounting sections of the flexible circuit board.

11. The illumination device according to claim 10, wherein the illumination device further comprises a transparent potting material, and the flexible circuit board and the light source are encapsulated by the potting material.

12. The illumination device according to claim 11, wherein the potting material is an elastic transparent silicone resin or PU.

13. The illumination device according to claim 10, wherein the light source is LED chip.

14. The flexible circuit board according to claim 2, wherein one of two adjacent connection sections is arranged at a first side of an adjacent device mounting section, and the other of the two adjacent connection sections is arranged at a second side of the device mounting section opposite to the first side.

15. The flexible circuit board according to claim 2, wherein adjacent device mounting sections and a connection section therebetween forms a sub-unit, wherein the device mounting sections of each sub-unit form a part of an adjacent sub-unit.

16. The flexible circuit board according to claim 15, wherein each sub-unit forms a U-shaped structure.

17. The flexible circuit board according to claim 14, wherein a gap between the adjacent device mounting sections forms a first deformation space, and a gap between the adjacent connection sections forms a second deformation space.

18. The flexible circuit board according to claim 2, wherein the device mounting sections and the connection sections are made in one piece.
